(19) United States
(12) Patent Application Publication
(10) Pub. No.: US 2010/0158063 A1
(43) Pub. Date: Jun. 24, 2010

(54) TUNABLE LASER WITH A DISTRIBUTED BRAGG GRATING COMPRISING A BRAGG SECTION MADE OF STRAINED BULK MATERIAL

(75) Inventors: Hélène Debregeas-Sillard, Le Chesnay (FR); Jean Decobert, Nozay (FR); Francois Lelarge, Paris (FR)

Correspondence Address: LOWE HAUPTMAN HAM & BERNER, LLP, 1700 DIAGONAL ROAD, SUITE 300, ALEXANDRIA, VA, 22314, US

(73) Assignee: ALCATEL LUCENT, Paris (FR)

(21) Appl. No.: 12/441,946

(22) PCT Filed: Sep. 19, 2007
(86) PCT No.: PCT/EP2007/059916

§ 371 Date: Apr. 1, 2009

(30) Foreign Application Priority Data
Sep. 22, 2006 (FR) 0608334

(51) Int. Cl. H01S 5/0625; H01S 5/323; H01S 5/125

(52) U.S. Cl. 372/45.011; 372/50.11

(57) ABSTRACT

The general field of the invention is that of tunable semiconductor devices with distributed Bragg grating, and more particularly that of tunable lasers with distributed Bragg grating termed DBRs. The device according to the invention comprises a passive Bragg section comprising a material whose optical index variations are controlled by an injection current, said material of the Bragg section is a strained bulk material, the strain applied to the bulk material being equal to at least 0.1%.

### CROSS-REFERENCE TO RELATED APPLICATIONS

The present Application is based on International Application No. PCT/EP2007/059916, filed on Sep. 19, 2007, which in turn corresponds to French Application No. 0608334, filed on Sep. 22, 2006, and priority is hereby claimed under 35 USC §119 based on these applications. Each of these applications are hereby incorporated by reference in their entirety into the present application.

### BACKGROUND OF THE INVENTION

1. Field of the Invention

The field of the invention is that of tunable lasers with distributed

Bragg grating. These lasers are notably used in optical telecommunication networks using wavelength division multiplexing (or WDM). Of course, the subject of the invention can be extended to any semiconductor optical device possessing a Bragg section which can be wavelength-tuned by injecting a current.

2. Description of the Prior Art

Tunable lasers with distributed Bragg grating are also known by the acronym DBR standing for Distributed Bragg Reflector. As represented in FIG. 1, a DBR laser 1 is a component monolithically integrating three sections each controlled by a different current: an active section 2 and two passive sections, i.e. a phase section 3 and a Bragg section 4. The current is brought to the various sections by means of the electrodes 21, 31 and 41.

The front face 5 and rear face 6 of the laser 1 are treated. The reflectivity of the rear face 6 is very low, of the order of 0.01% and the reflectivity of the front face 5 equals about 3%. A Fabry-Perot cavity is thus created between the front face 5 and the equivalent mirror of the Bragg section 4.

The active section 2 is the amplifying medium which provides the cavity with gain by way of a current I_{active} and allows the emission of a comb of so-called FP modes whose distribution is dictated by the optical characteristics of the Fabry-Perot cavity. This mode comb is represented in FIG. 2.

The Bragg section 4 is composed mainly of a material which is non-absorbent at the operating wavelength and comprises a Bragg grating 42, that is to say a periodic variation in the effective index. This structure behaves as a filter in reflection, centered on the wavelength λ_{Bragg}. The classical relation holds:

λ_{Bragg}=2·n_{eff}·Λ

where n_{eff} is the effective index of the guide and Λ the period of the Bragg grating.

The variation in the reflection coefficient R_{Bragg} of this Bragg filter as a function of wavelength is represented in FIG. 2. When a current I_{Bragg} is injected, the carrier density increases, thereby decreasing the effective index and consequently the wavelength λ_{Bragg}. A displacement of the curve for the variation in the reflection coefficient R_{Bragg} is then obtained.

Tunability is based on this principle as illustrated in FIG. 2. The laser emission is performed on the FP mode having the largest reflectivity on the Bragg filter. This mode selected by the filter is represented in bold in FIG. 2. When the Bragg filter is tuned by injecting current into the Bragg section, the FP modes are then emitted successively, and tunability is obtained through mode jumps. When current is injected into the phase section, the effective index decreases in the same manner as the effective index of the Bragg section, thereby shifting the comb of the FP modes towards the low wavelengths and thus allowing fine tuning of the emission wavelength. It is thus possible to attain all the wavelengths covered through the tunability of λ_{Bragg}. One speaks of quasi-continuous tuning.

Through these means, it is possible to vary the emission wavelength of a DBR tunable laser over a span Δλ_{Bragg} of 16 nanometers.

To summarize, in the cavity, a mode 8 dictated by the Bragg section oscillates between the front and rear faces, this mode is symbolized by a semi-circular arrow in FIG. 1 and the laser emission 7 of a fraction of this radiation takes place through the front face 5.

However, for a certain number of applications, in particular in the field of optical telecommunications, the tunability range obtained is insufficient. For example, tunability of the order of 35 nanometers is required in order to explore the entire C band (1528 nm-1562 nm) or L band (1570 nm-1605 nm) of optical telecommunications. At present, to achieve this wide tunability range, it is necessary either to use the interaction between more sophisticated gratings such as sampled gratings, gratings with periodically variable spacing or to use a succession of Bragg gratings with shifted spacings or to add together the tunability ranges of several DBR lasers by using for example a coupler.

### SUMMARY OF THE INVENTION

The aim of the invention is to sufficiently increase the tunability range of the Bragg section of the DBR or of any section using variation of carriers by current injection. This makes it possible notably to simplify the design of the final component. Thus, it is possible to
cover the C or L band with a single component;
use only two DBR lasers instead of three;
obtain a larger tolerance on the characteristics and the manufacture of the sampled gratings, . . .
reduce the currents required in the Bragg sections. This yields ultra-fast tunability of the order of a few nanoseconds.

The core of the invention is to make the Bragg section of strained bulk material. It is demonstrated that there is a substantial modification of one of the effects, called bandfilling, intervening on the wavelength tunability range Δλ_{Bragg}.

More precisely, the subject of the invention is a tunable semiconductor device with distributed Bragg grating comprising a passive Bragg section comprising a material whose optical index variations are controlled by an injection current, characterized in that said material of the Bragg section is a strained bulk material composed of layers of one and the same material, each layer having a lattice parameter, the strain of the bulk material being equal to the relative variation in the lattice parameter between the various layers.

Advantageously, the strain applied to the bulk material is equal to at least 0.1%; the material comprises a succession of layers; some strained, others unstrained.

Advantageously, the strain is imposed by compression or by tension.

Advantageously, the material is of quaternary material, the quaternary material is InGaAsP, the wavelength corresponding to the maximum photoluminescence is then equal to 1.45 micrometers, said material being known by the name Q 1.45.

Preferably, this device applies to tunable lasers of DBR type.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 represents a general view of a tunable laser with distributed Bragg grating;

FIG. 2 represents the principle of tunability by means of a tunable Bragg grating;

FIG. 3 represents the variation in the absorption of the material as a function of energy;

FIG. 4 represents the diagram of energy bands for an unstrained bulk material;

FIG. 5 represents the diagram of energy bands for a strained bulk material;

FIG. 6 represents the diagram of energy bands for a bulk material under extension;

FIG. 7 represents the variation in index as a function of wavelength for materials with lattice matching, by compression or by tension.

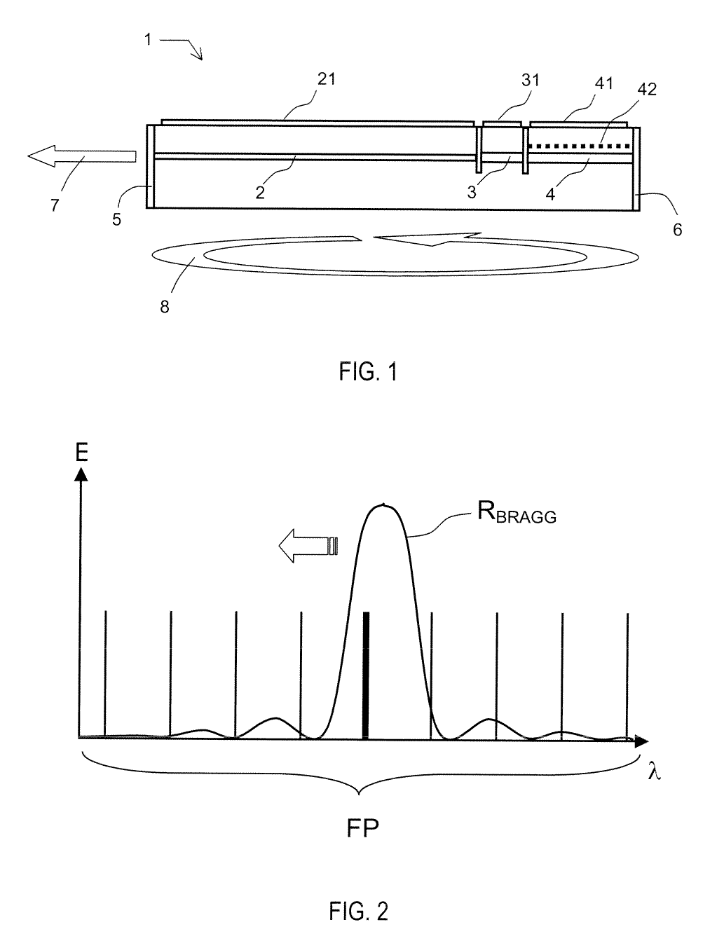

### DETAILED DESCRIPTION OF THE INVENTION

The tunability of the DBR is given by the following relation:

$$Δ {λ}_{Bragg} = 2 \cdot {Γ}_{Q} \cdot \frac{d {n}_{Q}}{d N} \cdot Δ N \cdot Λ$$

where Γ_{Q} is the confinement of the optical mode in the guide material where the carriers are situated;

ΔN is the variation in carrier density related to the current injection; dn_{Q}/dN is the variation in index of the material with carrier density.

The object of the invention is to widen Δλ_{Bragg} by increasing the variation in index of the material with carrier density dn_{Q}/dN . But to preserve a maximum confinement factor Γ_{Q}, of the order of 70%, it is necessary to employ a thick bulk material or one optionally comprising a few intercalated fine layers. The factor Γ_{Q} is degraded too much by quantum well structures for them to be used. The index variation dn_{Q}/dN is the sum of three main effects, viz:
The plasma effect;
The renormalization of the gap also called “bandgap shrinkage”;
The filling of the bands also called “bandfilling”.

The first two effects do not depend on modifiable parameters of the material. The object of the invention is therefore to increase the “bandfilling” effect.

The absorption of a photon causing an electron to pass from the energy E_{V} of the valence band to the energy E_{C} of the conduction band is possible only if the level E_{V} is occupied and the level E_{C} free. The absorption can be modeled by:

$$α ( E ) = \frac{{C}_{hh}}{E} \cdot \sqrt{E - {E}_{g}} [ \begin{matrix}{f}_{v} ( {E}_{vh} ) - \\ {f}_{c} ( {E}_{ch} )\end{matrix} ] + \frac{{C}_{lh}}{E} \cdot \sqrt{E - {E}_{g}} [ \begin{matrix}{f}_{v} ( {E}_{vl} ) - \\ {f}_{v} ( {E}_{cl} )\end{matrix} ]$$

Cₕₕ and Cᵢₕ are the absorption coefficients of the transitions arising from the light-hole and heavy-hole bands. They are characteristic of the material.

Eᵥₕ and E_{ch} correspond to the energies of transition from the heavy-hole band while Eᵥ₁ and E_{cl} correspond to the energies of transition from the light-hole band. fᵥ(E) and f_{c}(E) are the probabilities that an energy level E of the valence or conduction band is occupied by an electron.

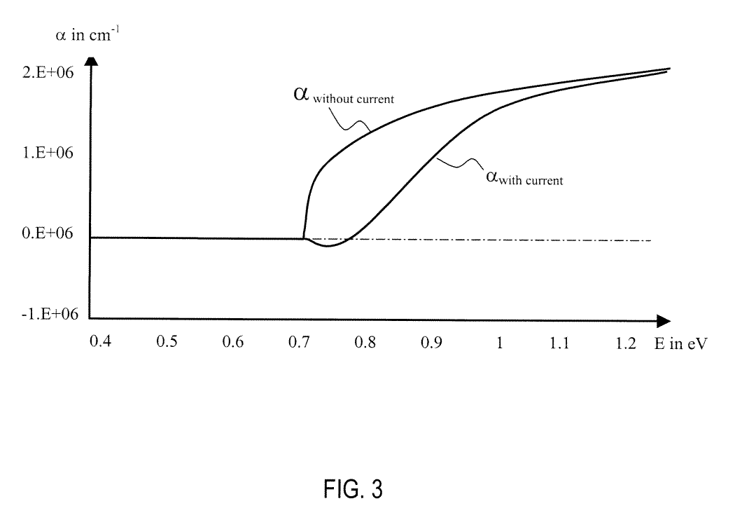

During current injection, the bands fill with carriers. At energies slightly above the gap energy E_{g}, the terms fᵥ(E)−f_{c}(E) become zero or negative. A reduction of the absorption, and even optionally of the gain, is then obtained at these energies. This effect is illustrated in FIG. 3, where the absorption as a function of energy is plotted with and without carrier injection.

Now, the variation in index of a material at an energy E₀ is linked to the variation in absorption of this material over the whole of the energy spectrum by the Kramers-Krönig relation:

$$Δ n ( {E}_{0} ) = \frac{ℏ c}{π} \cdot P {\int }_{0}^{∞} \frac{Δ α ( E )}{{E}^{2} - {E}_{0}^{2}} d E$$

in which P represents the principal part of the Cauchy integral and E₀ the work energy. A considerable reduction in the optical index around E_{g} is thus obtained. For example, for a DBR laser whose operating wavelength is equal to 1.55 micrometers, the energy E0 equals 0.8 eV.

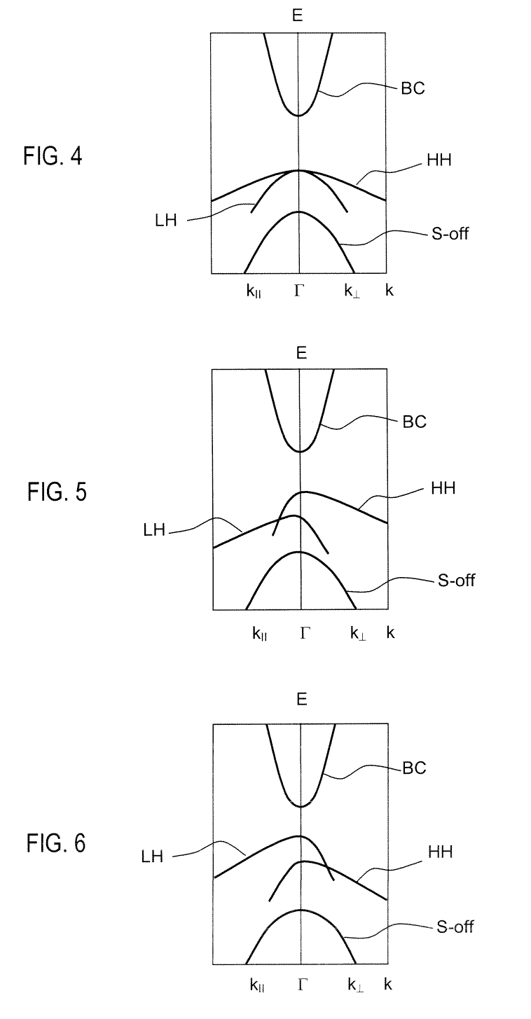

To increase the bandfilling effect, it is therefore necessary to accentuate this reduction in absorption at energies close to the gap. For this purpose, strained materials are used. FIGS. 4, 5 and 6 represent the energy diagrams of a direct-gap semiconductor bulk material, as a function of the moment k in the directions parallel k// and perpendicular k⊥ to the direction of growth.

In these figures, the conduction band is denoted BC, the heavy-hole and light-hole bands are respectively denoted HH and LH, the split-off band is denoted S-off.

FIG. 4 corresponds to a lattice matching material. The material is isotropic: the bands are identical in the directions k// and k⊥. The bands of the light holes LH and the bands of the heavy holes HH have the same energy level: they are degenerate. The injected carriers are therefore distributed over the two bands.

To increase the variation in absorption and in particular the filling of the bands, the principle of the device according to the invention is to lift the degeneracy between the bands of the light holes and the bands of the heavy holes. The carriers are then distributed in a single band, allowing a more considerable reduction in the absorption. Moreover, the degeneracy lifting will give rise either to a reduction in the effective mass of the heavy holes, or a reduction in the effective mass of the light holes, enabling the HH or LH band relevant to this reduction to be made narrower, thus favoring the filling of the carriers up to high energies.

To produce the strain, it is possible to apply a biaxial strain to the material of the Bragg section.

In the case of a compressive strain, the heavy-hole HH band becomes higher in energy as indicated in FIG. 5: the injected carriers are distributed preferably in the HH band. Additionally, the effective mass of the heavy holes is lower, thereby corresponding to an HH energy band narrower in the direction k_{∥}, as seen in FIG. 5. This effect gives rise to faster filling of the heavy-hole band, correspondingly increasing the effect of the band filling. In these structures under compression, a large variation is therefore obtained in the absorption implementing heavy holes, that is to say corresponding to a transverse electric polarization denoted TE of the optical mode. In a conventional DBR laser, the light emitted by the gain section is actually TE-polarized. On the other hand, for light polarized in transverse magnetic mode denoted TM, the bandfilling effect is low.

In the case of a tensile strain, the light-hole LH band becomes higher in energy as indicated in FIG. 6. The injected carriers are distributed in the LH band. In this case, a bandfilling effect which is considerable for the TM polarization and low as regards TE polarization is therefore obtained. To be used in a DBR, this type of material therefore requires an active structure suitable for emitting in TM mode.

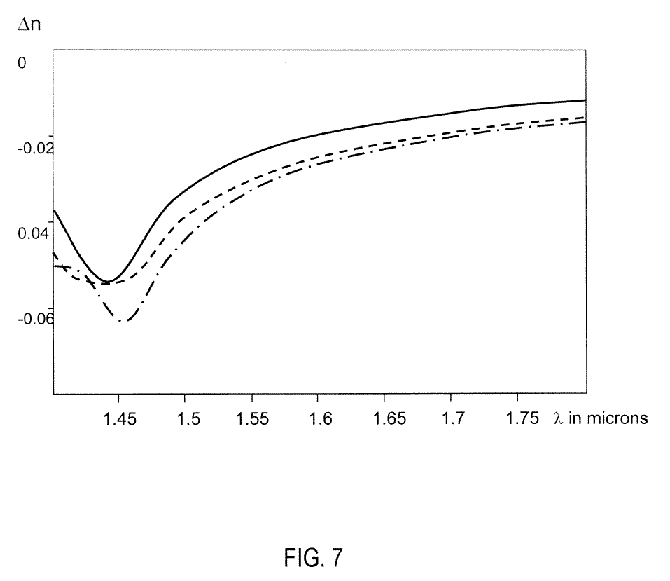

FIG. 7 gives simulation results for the index variation Δn as a function of wavelength λ, this variation being due solely to the bandfilling effect, obtained for a carrier density of 2.10¹⁸ cm⁻³. The solid curve corresponds to an unstrained bulk material. The dotted curve corresponds to bulk material strained by compression to +1%: an improvement of 25% in the index variation is obtained at the operating wavelength of 1.55 micrometers, thereby signifying an increase of 25% in the tunability. With a material under tension to −0.7%, corresponding to the dashed curve, an increase of 45% in the index variation is obtained, on condition that the TM mode is operative.

There exist various types of materials making it possible to produce a strained Bragg section. It is possible, for example, to use multi-quantum well structures also called MQW structures. However, it is not possible to produce MQW structures with such considerable confinement ratios Γ_{Q} as in bulk materials, since the carriers are not accumulated in the barriers which therefore do not participate in the tunability. Typically, the maximum values of Γ_{Q} in the wells are about 35%, as against 70% in bulk material. Consequently, a “bulk” material making it possible to achieve a high confinement ratio is preferably used to produce a Bragg section according to the invention.

The production of strained bulk material is a commonplace technique. It consists in depositing layers of material, for example by epitaxial methods, with different lattice parameters. Either compressive or tensile biaxial strains are thus created, depending on whether the lattice parameter pertaining to the various layers increases or decreases. As a function of the material used and of its thickness, there exists a maximum strain threshold beyond which mechanical relaxation and dislocation mechanisms may appear. To push back these limits, it is possible to insert fine layers with an opposite strain. For example, the layers are under tension in a material under compression so as to compensate for the mechanical effects. In a preferential manner, the strain applied to the bulk material may attain a few tenths of a percent.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. A tunable semiconductor device with distributed Bragg grating comprising a passive Bragg section comprising a material whose optical index variations are controlled by an injection current, wherein the said material of the Bragg section is a strained bulk material, composed of layers of one and the same material, each layer having a lattice parameter, the strain of the bulk material being equal to the relative variation in the lattice parameter between the various layers.

2. The tunable semiconductor device with distributed Bragg grating as claimed in claim 1, wherein the strain applied to the bulk material is equal to at least 0.1%.

3. The tunable semiconductor device with distributed Bragg grating as claimed in claim 1, wherein the material comprises a succession of layers, some strained, others unstrained.

4. The tunable semiconductor device with distributed Bragg grating as claimed in claim 1, wherein the strain is imposed by compression.

5. The tunable semiconductor device with distributed Bragg grating as claimed in claim 1, wherein the strain is imposed by tension.

6. The tunable semiconductor device with distributed Bragg grating as claimed in claim 6, wherein the strained bulk material is of quaternary material.

7. The tunable semiconductor device with distributed Bragg grating as claimed in claim 6, wherein the quaternary material is InGaAsP, the wavelength corresponding to the maximum photoluminescence being equal to 1.45 micrometers, said material being known by the name
Q 1.45.

8. The tunable semiconductor device with distributed Bragg grating as claimed in claim 1, wherein the device is a tunable laser of DBR type.

9. The tunable semiconductor device with distributed Bragg grating as claimed in claim 2, wherein the material comprises a succession of layers, some strained, others unstrained.

10. The tunable semiconductor device with distributed Bragg grating as claimed in claim 2, wherein the strain is imposed by compression.

11. The tunable semiconductor device with distributed Bragg grating as claimed in claim 3, wherein the strain is imposed by compression.

12. The tunable semiconductor device with distributed Bragg grating as claimed in claim 2, wherein the strain is imposed by tension.

13. The tunable semiconductor device with distributed Bragg grating as claimed in claim 3, wherein the strain is imposed by tension.

14. The tunable semiconductor device with distributed Bragg grating as claimed in claim 2, wherein the strained bulk material is of quaternary material.

15. The tunable semiconductor device with distributed Bragg grating as claimed in claim 3, wherein the strained bulk material is of quaternary material.

16. The tunable semiconductor device with distributed Bragg grating as claimed in claim 4, wherein the strained bulk material is of quaternary material.

17. The tunable semiconductor device with distributed Bragg grating as claimed in claim 5, wherein the strained bulk material is of quaternary material.

18. The tunable semiconductor device with distributed Bragg grating as claimed in claim 2, wherein the device is a tunable laser of DBR type.

19. The tunable semiconductor device with distributed Bragg grating as claimed in claim 3, wherein the device is a tunable laser of DBR type.

20. The tunable semiconductor device with distributed Bragg grating as claimed in claim 4, wherein the device is a tunable laser of DBR type.
